(19) United States
(12) Patent Application Publication
(10) Pub. No.: US 2026/0363110 A1
(43) Pub. Date: Nov. 12, 2026

(54) SEMICONDUCTOR DEVICE, STSYTEM, AND METHOD FOR MANUFACTURING SEMICONDUCTOR DEVICE

(71) Applicant: Yangtze Memory Technologies Co., Ltd., Wuhan (CN)

(72) Inventors: Libo Mei, Wuhan (CN); Liang Xiao, Wuhan (CN); Huan Wang, Wuhan (CN); Bo Wen, Wuhan (CN)

(21) Appl. No.: 19/287,968

(22) Filed: Aug. 1, 2025

(30) Foreign Application Priority Data
May 12, 2025 (CN) 202510608304.4

(51) Int. Cl. H10W 70/65; H10B 12/00; H10B 41/35; H10B 41/41; H10B 43/35; H10B 43/40; H10B 80/00; H10W 70/60; H10W 70/63; H10W 70/685; H10W 90/00

(52) U.S. Cl. CPC H10W 70/65; H10B 12/50; H10B 41/35; H10B 41/41; H10B 43/35; H10B 43/40; H10B 80/00; H10W 70/611; H10W 70/635; H10W 70/685; H10W 90/792

(57) ABSTRACT

Disclosed are a semiconductor device, a system, and a method for manufacturing a semiconductor device. The semiconductor device includes a first semiconductor structure and a second semiconductor structure. The first semiconductor structure includes a function layer, a wiring layer arranged on the function layer, a bonding layer arranged on the wiring layer, and a first via. The wiring layer includes metal layers. The bonding layer includes a first metal pad. The first via extends through at least one metal layer of the metal layers, and extends between a second metal pad of a first one of the metal layers and the first metal pad. The second semiconductor structure is bonded with the first semiconductor structure by the bonding layer.

### CROSS-REFERENCE TO RELATED APPLICATIONS

This application claims the benefit of priority to Chinese Application No. 202510608304.4 filed on May 12, 2025, which is hereby incorporated by reference in its entirety.

### FIELD OF TECHNOLOGY

The disclosure relates to semiconductor technology, and in particular, to a semiconductor device, a system including a memory, and a method for manufacturing a semiconductor device.

### BACKGROUND

A semiconductor structure includes an electrical connection for electrically connecting two metal layers therein, such as two adjacent metal layers. The semiconductor structure may further includes an electrical connection for electrically connecting a bonding layer and an adjacent metal layer. The electrical connections are formed as Damascus structures of copper. The Damascus structures are generally adopted in an electrochemical plating (ECP) process using copper.

With the development of semiconductor technology and the requirement for the pitch shrink of the semiconductor structure, the size of the semiconductor structure becomes smaller and smaller, and thus the wiring density in the semiconductor structure is increased. In this case, there is a challenge for the reliability and the complexity of the electrical connections for electrically connecting two metal layers or a bonding layer and a metal layer in the semiconductor structure, particularly, which are not adjacent to each other.

### SUMMARY

According to one aspect of the present disclosure, a semiconductor device is provided. The semiconductor device may include a first semiconductor structure. The first semiconductor device may include a function layer. The first semiconductor device may include a wiring layer arranged on the function layer and including metal layers. The first semiconductor device may include a bonding layer arranged on the wiring layer and including a first metal pad. The first semiconductor device may include a first via extending through at least one metal layer of the metal layers, and extending between a second metal pad of a first one of the metal layers and the first metal pad. The semiconductor device may include a second semiconductor structure bonded with the first semiconductor structure by the bonding layer.

In some implementations, the first via may extend through a plurality of metal layers of the metal layers.

In some implementations, the first via may extend through one metal layer of the metal layers.

In some implementations, the first semiconductor structure may further include a second via extending between a third metal pad of a second one of the metal layers and a fourth metal pad of the bonding layer without extending through the metal layers.

In some implementations, the first semiconductor structure may further include a third via extending between two metal pads of two adjacent ones of the metal layers. In some implementations, the first may have a depth-to-width ratio greater than a depth-to-width ratio of the third via.

In some implementations, a metal material of the third via may be different from metal material of the first via. In some implementations, a cross-section of the wiring layer may include a part of the third via and a part of the first via.

In some implementations, the third via may include copper, and the first via may include at least one of tungsten, titanium or aluminium.

In some implementations, an area of a cross-section of the first via at an end for contacting with the first metal pad may be larger than an area of a cross-section of the first via at an end for contacting with the second metal pad.

In some implementations, the second semiconductor structure maybe bonded with the first semiconductor structure by another bonding layer of the second semiconductor structure and the bonding layer. In some implementations, the first semiconductor structure may be one of a memory chip or a peripheral chip for the memory chip, and the second semiconductor structure may be the other one of the memory chip or the peripheral chip.

In some implementations, the memory chip may be a NAND chip or a DRAM chip.

According to another aspect of the present disclosure, a system is provided. The system may include a memory. The memory may include a first semiconductor structure. The first semiconductor structure may include a function layer. The first semiconductor structure may include a wiring layer arranged on the function layer and including metal layers. The first semiconductor structure may include a bonding layer arranged on the wiring layer and including a first metal pad. The first semiconductor structure may include a first via extending through at least one metal layer of the metal layers and extending between a second metal pad of a first one of the metal layers and the first metal pad. The memory may include a second semiconductor structure bonded with the first semiconductor structure by the bonding layer. The system may include a controller configured to control the memory.

In some implementations, the first semiconductor structure may be one of a memory chip of a peripheral chip for the memory chip, and the second semiconductor structure may be the other one of the memory chip or the peripheral chip.

According to a further aspect of the present disclosure, a method for manufacturing a semiconductor device is provided. The method may include forming a first semiconductor structure. The forming a first semiconductor structure may include forming a function layer. The forming a first semiconductor structure may include forming a wiring layer on the function layer, and the wiring layer including metal layers. The forming a first semiconductor structure may include forming a first via in the wiring layer. The forming a first semiconductor structure may include forming a bonding layer on the wiring layer, and the bonding layer may include a first metal pad. The first via may extend through at least one metal layer of the metal layers and extend between a second metal pad of a first one of the metal layers and the first metal pad. The method may include bonding the first semiconductor structure with a second semiconductor structure by the bonding layer.

In some implementations, forming the first via in the wiring layer may include etching the wiring layer to form a first hole. In some implementations, forming the first via in the wiring layer may include depositing, by a physical vapor deposition (PVD) or chemical vapor deposition (CVD) process, metal material into the first hole, to form the first via.

In some implementations, forming the bonding layer on the wiring layer may include depositing insulation material on the wiring layer to form an insulation layer. In some implementations, forming the bonding layer on the wiring layer may include etching the insulation layer to form a second hole passing though the insulation layer and directly over the first via. In some implementations, forming the bonding layer on the wiring layer may include filling the second hole with metal material to form the first metal pad. In some implementations, forming the bonding layer on the wiring layer may include polishing, by a chemical mechanical planarization (CMP) process, the insulation layer with the first metal pad, to form the bonding layer.

In some implementations, forming the first semiconductor structure may further include forming a second via in the wiring layer, and the second via may extend between a third metal pad of a second one of the metal layers and a fourth metal pad of the bonding layer without extending through the metal layers.

In some implementations, the wiring layer may further include a third via extending between two metal pads of two adjacent ones of the metal layers. In some implementations, the first via may have a depth-to-width ratio greater than a depth-to-width ratio of the third via.

In some implementations, metal material of the third via may be different from metal material of the first via. In some implementations, a cross-section of the wiring layer may include a part of the third via and a part of the first via.

In some implementations, the third via may include copper, and the first via may include at least one of tungsten, titanium or aluminium.

In some implementations, bonding the first semiconductor structure with the second semiconductor structure by the bonding layer may include bonding the first semiconductor structure with a second semiconductor structure by another bonding layer of the second semiconductor structure and the bonding layer. In some implementations, the first semiconductor structure may be one of a memory chip or a peripheral chip for the memory chip, and the second semiconductor structure may be the other one of the memory chip or the peripheral chip.

### BRIEF DESCRIPTION OF THE DRAWINGS

The accompanying drawings, which are incorporated herein and form a part of the description, illustrate embodiments of the present disclosure and, together with the description, further serve to explain the principles of the present disclosure and to enable those skilled in the art to make and use the present disclosure.

FIGS. 1A is a schematic cross-section view of an example of a first semiconductor structure according to the embodiments of the present disclosure;

FIGS. 1B is a schematic cross-section view of another example of a first semiconductor structure according to the embodiments of the present disclosure;

FIGS. 1C is a schematic cross-section view of another example of a first semiconductor structure according to the embodiments of the present disclosure;

FIG. 2 is an enlarged view of a schematic cross-section view of an arrangement in a first semiconductor structure according to the embodiments of the present disclosure;

FIG. 3 is a schematic cross-section view of another example of a first semiconductor structure according to the embodiments of the present disclosure;

FIG. 4 is a schematic cross-section view of another example of a first semiconductor structure according to the embodiments of the present disclosure;

FIG. 5 illustrates further cross-section views of a first semiconductor structure according to the embodiments of the present disclosure;

FIG. 6A is a schematic cross-section view of an example of a semiconductor device with two semiconductor structures bonded with each other according to the embodiments of the present disclosure;

FIG. 6B is a schematic cross-section view of another example of a semiconductor device with two semiconductor structures bonded with each other according to the embodiments of the present disclosure;

FIG. 7 is a schematic cross-section view of a HBM device including the semiconductor device according to the embodiments of the present disclosure;

FIG. 8 is a schematic block diagram of an example of a system according to the embodiments of the present disclosure;

FIG. 9 is a schematic flowchart of an example of a method for manufacturing a semiconductor device according to the embodiments of the present disclosure;

FIG. 10 is a schematic flowchart of an example of a process for forming a first semiconductor structure of FIG. 9 according to the embodiments of the present disclosure;

FIG. 11 is a schematic cross-section view showing a forming of a function layer according to the embodiments of the present disclosure;

FIG. 12 is a schematic cross-section view showing a forming of a wiring layer according to the embodiments of the present disclosure;

FIG. 13 is a schematic cross-section view showing a forming of holes in the wiring layer according to the embodiments of the present disclosure;

FIG. 14 is a schematic cross-section view showing a forming of vias in the wiring layer according to the embodiments of the present disclosure;

FIG. 15 is a schematic cross-section view showing a forming of an insulation layer on the wiring layer according to the embodiments of the present disclosure;

FIG. 16 is a schematic cross-section view showing a forming of holes in the insulation layer according to the embodiments of the present disclosure; and

FIG. 17 is a schematic cross-section view showing a forming of metal pads and a bonding layer according to the embodiments of the present disclosure.

### DETAILED DESCRIPTION OF EMBODIMENTS

Embodiments of the disclosure will be described below in conjunction with the accompanying drawings. Although some embodiments of the disclosure are shown in the accompanying drawings, the disclosure can be implemented in various forms, and these embodiments are provided to understand the disclosure. The accompanying drawings and the embodiments of the disclosure are merely illustrative.

Various steps described in a method embodiment of the disclosure can be executed in different orders and/or in parallel. In addition, the method embodiment can include additional steps and/or will not execute the steps shown. The scope of the disclosure is not limited in this respect.

The terms “comprise,” “include,” and their variations used herein indicate open-ended inclusions, e.g., “comprise, but is not limited to” and “include, but is not limited to.” The term “based on” means “at least partially based on.” The term “an embodiment” indicates “at least one embodiment.” The term “another embodiment” indicates “at least one further embodiment.” The term “some embodiments” indicates “at least some embodiments.” The definitions relevant to other terms are set forth in the description below.

The concepts “first,” “second,” etc. mentioned in the disclosure are merely used to distinguish between different apparatuses, modules, or units, instead of defining an order or interdependence relation of functions executed by the apparatuses, modules, or units.

The modifiers “a,” “an,” and “a plurality of” mentioned in the disclosure are illustrative rather than restrictive. Those skilled in the art should understand that these modifiers should be interpreted as “one or more” unless clearly indicated otherwise in the context.

With the development of semiconductor technology and the requirement for the pitch shrink of the semiconductor structure, the size of the semiconductor structure becomes smaller and smaller, and thus the wiring density in the semiconductor structure is increased, particularly in a bonding layer and a wiring layer as described below, which are formed in a BEOL (Back-End of Line) process in a manufacturing process of the semiconductor structure. In this case, there is a challenge for the reliability and the complexity of the electrical connections for electrically connecting two metal layers or a bonding layer and a metal layer in the semiconductor structure, which are not adjacent to each other.

Conventionally, in a semiconductor structure including the bonding layer and the wiring layer, the Damascus structure of copper is formed for electrically connecting two adjacent metal layers or electrically connecting a bonding layer and an adjacent metal layer of the semiconductor structure. The Damascus structure generally includes a via and a pad. The via extends between the two adjacent metal layers or between the bonding layer and the adjacent metal layer, and electrically contacts with the pad in one of the two adjacent metal layers or in one of the bonding layers and the adjacent metal layers.

In the semiconductor structure, there may be a need for electrically connecting two metal layers which are not adjacent to each other or electrically connecting the bonding layer and a metal layer, which is not adjacent to the bonding layer. In this case, two or more Damascus structures are stacked vertically with each other. In the stack, in some embodiments, there may be some Damascus structures stacked directly over one another with one via of a Damascus structure contacting with one pad of another Damascus structure. In the stack, in some further embodiments, there may be some Damascus structures stacked not directly over one another and electrically connected with each other by means of metal pads and metal lines of the metal layers therebetween. Thereby, a sufficient overlap window may be beneficial to ensure a well electrical connection between each via of the Damascus structures and a corresponding metal pad. However, this arrangement of the stack often has a large area in the semiconductor structure. Further, the Damascus structures in the stack may not be well aligned with each other, which may degrade the reliability. Further, the stack of such Damascus structures is generally complex, and its cost is expensive.

In view of the above, the present disclosure provides an improved semiconductor device. The semiconductor device includes a first semiconductor structure and a second semiconductor structure. The first semiconductor structure includes a function layer, a wiring layer arranged on the function layer, a bonding layer arranged on the wiring layer, and a first via. The wiring layer includes metal layers. The bonding layer includes a first metal pad. The first via extends through at least one metal layer of the metal layers and extends between a second metal pad of a first one of the metal layers and the first metal pad. The second semiconductor structure bonded with the first semiconductor structure by the bonding layer. Such configuration may reduce the area of the wiring and increase the reliability of the wiring. Moreover, it may lower manufacturing costs and complexity.

The embodiments of the first semiconductor structure of the semiconductor device will be described below with reference to the figures. It can be understood that the second semiconductor structure of the semiconductor device may have a structure similar to or different from that of the first semiconductor structure.

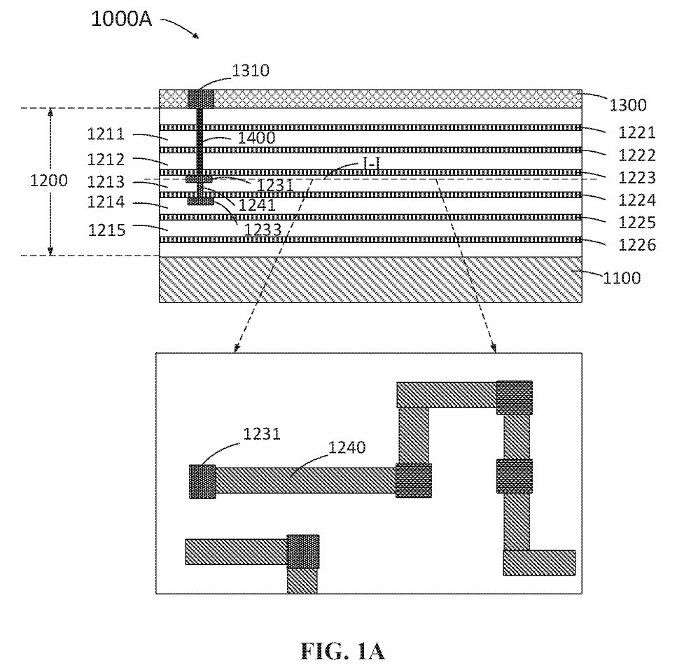

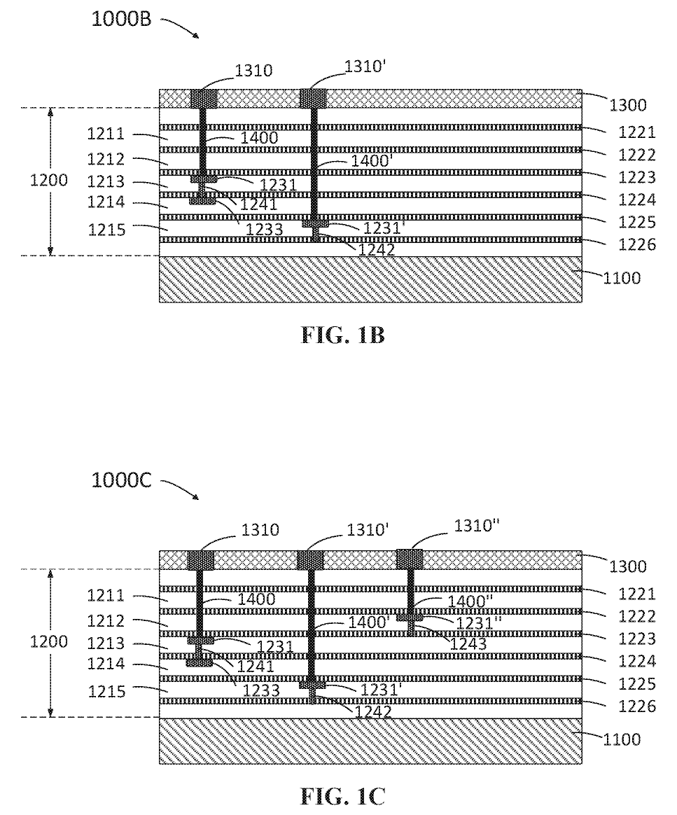

FIG. 1A is a schematic cross-section view of an example of a first semiconductor structure 1000A according to the embodiments of the present disclosure. The first semiconductor structure 1000A may be one of a memory chip or a peripheral chip for the memory chip, and the second semiconductor structure may be the other one of the memory chip or the peripheral chip. In some examples, the memory chip may be a NAND chip or a DRAM chip.

As shown in FIG. 1A, the first semiconductor structure 1000A includes a function layer 1100, a wiring layer 1200, a bonding layer 1300, and a first via 1400. The function layer 1100 serves for particular functions of the first semiconductor structure 1000A, such as the functions of a memory chip or a peripheral chip. As an example, in a case that the first semiconductor structure 1000A is the memory chip, the function layer 1100 may include structure for a memory cell. As another example, in a case that the first semiconductor structure 1000A is the peripheral chip, the function layer 1100 may include structure for a peripheral circuit. The wiring layer 1200 is arranged on the function layer 1100 and serves for electrically connecting the function layer 1100 to the other portion of the semiconductor device, e.g., to the second semiconductor structure through the bonding layer 1300.

The wiring layer 1200 includes layers 1211, 1212, 1213, 1214, and 1215. It is understood that these layers are for the purpose of illustration without limiting the scope of the present disclosure, and the number of the layers is not limited to five. Other numbers of layers are possible for the stack of the layers. The layers 1211, 1212, 1213, 1214, and 1215 each include a metal layer and a dielectric layer. The metal layers and the dielectric layers are alternately arranged, such that the dielectric layers may electrically isolate the metal layers from each other. The metal layers may include copper or other conductive material, and the dielectric layers may include silicon oxide or other insulating material. Each of the metal layers may be a layer with electrical connection(s) embodied in the dielectric material. The electrical connection may include at least one of a metal line and a metal pad.

For example, the bottom of FIG. 1A shows a transverse cross-section view of an example of a metal layer in the layer 1213, taken along line I-I in the cross-section view of the first semiconductor structure 1000A. The metal layer may include a metal line 1240, and other metal lines which are not specifically indicated by reference numbers. The metal layer may further include a metal pad 1231 (which is also referred to as a second metal pad below), and other metal pads which are not specifically indicated by reference numbers. In some embodiments, the metal pad of the metal layer may be formed as a portion of the corresponding metal line. In some further embodiments, the metal pad of the metal layer may be formed as an element separated from and electrically connected with the corresponding metal line.

The dielectric layers in the layers 1211, 1212, 1213, 1214, and 1215 each may be arranged with one or more via(s) therein, and the via(s) may extend through the dielectric layer. In some embodiments, the via(s) is/are used for electrically connecting two metal layers adjacent to the dielectric layer, by electrically connecting with two metal pads in the two metal layers respectively. In some further embodiments, the via(s) is/are used for electrically connecting a metal layer and a bonding layer adjacent to the dielectric layer, by electrically connecting with two metal pads in the metal layer and the bonding layer respectively. The via and one electrically connected metal pad may form a Damascus structure.

For example, as shown in FIG. 1A, the metal pad 1231 and the via 1241 may form a Damascus structure. Further, the via 1241 of the Damascus structure may be further electrically connected with another metal pad 1233 of a metal layer in layer 1214. Thereby, the via 1241 electrically connects two metal layers in the layers 1213 and 1214, respectively. It can be understood that the Damascus structure shown in FIG. 1A is only an example, and there may be other Damascus structure(s) arranged in the wiring layer 1200. Further, it can be understood that the Damascus structure may be formed in the wiring layer 1200 during the forming of the wiring layer 1200, and it may be formed as a portion of the wiring layer 1200.

In some embodiments, the Damascus structure in the wiring layer 1200 may include a Single Damascus structure; and in the forming of the Single Damascus structure, the via (such as the via 1241) is etched and filled with copper first, and then the metal layer (such as the metal layer in the layer 1213) is etched and filled with copper to form the metal pad (such as the metal pad 1231). In some further embodiments, the Damascus structures in the wiring layer 1200 may include a Double Damascus structure; and in the forming of the Double Damascus structure, the via (such as the via 1241) and the metal layer (such as the metal layer in the layer 1213) are etched first, and then they are filled with copper together to form the Damascus structure. The wiring layer 1200 may include at least one of the Single Damascus structure and the Double Damascus structure.

In some embodiments, the wiring layer 1200 may further include layers 1221, 1222, 1223, 1224, 1225, and 1226. The wiring layer 1200 may further have a top dielectric layer over the layer 1221. The layers 1221, 1222, 1223, 1224, 1225, and 1226 each may be a cap layer arranged on a corresponding metal layer, to prevent a diffusion of the metal material in the metal layer and to further electrically isolate the metal layers. In some embodiments, the cap layer may include material which is the same as the material of the dielectric layers in the layers 1211, 1212, 1213, 1214, and 1215. In some embodiments, the cap layer may include material which is different from the material of the dielectric layers in the layers 1211, 1212, 1213, 1214, and 1215. For example, the cap layers may include silicon nitride, carbon-doped silicon dioxide, or other materials.

The bonding layer 1300 is arranged on the wiring layer 1200, and includes a first metal pad 1310. For example, the bonding layer 1300 is arranged on the top dielectric layer of the wiring layer 1200. The first metal pad 1310 in the bonding layer 1300 is arranged directly over the first via 1400. The first via 1400 is arranged in the wiring layer 1200, and the first via 1400 extends through at least one metal layer of the metal layers of the wiring layer 1200, and extends between a second metal pad of a first one of the metal layers of the wiring layer 1200 and the first metal pad 1310. For example, as shown in FIG. 1A, the first via 1400 extends through two metal layers, which are in the layers 1211 and 1212 respectively, and extends between a second metal pad 1231 of a metal layer in the layer 1213 and the first metal pad 1310.

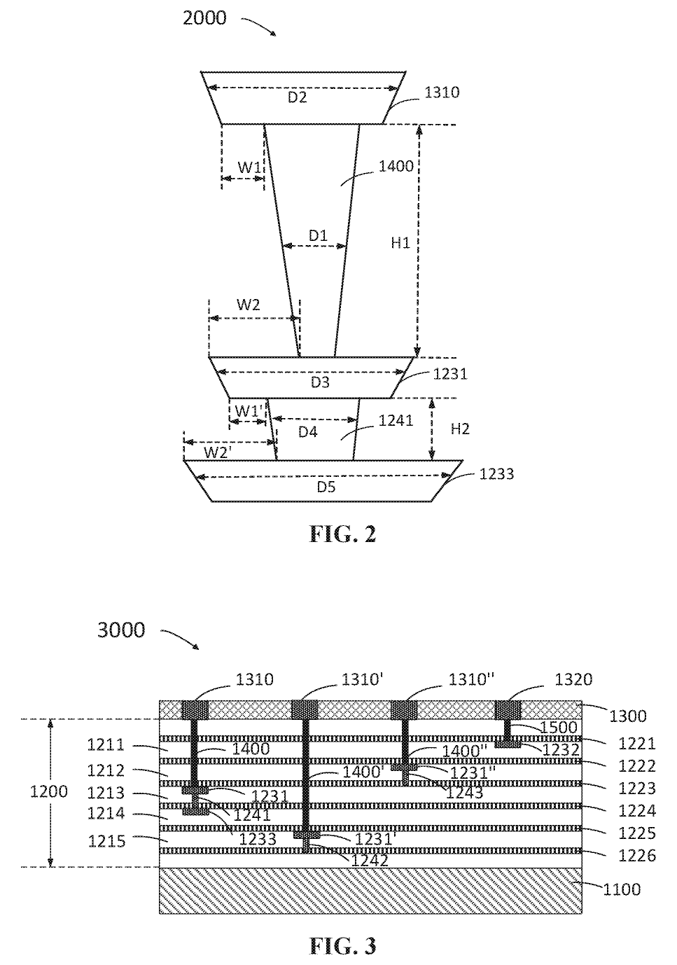

An enlarged view of a schematic cross-section view of an arrangement of the first via 1400, the first metal pad 1310, the second metal pad 1231, the via 1241 and the metal pad 1233 is shown in FIG. 2. As shown in FIG. 2, the first via 1400 has a first diameter D1 and a height H1. The first diameter D1 of the first via 1400 is gradually decreased in a direction from an end of the first via 1400 for contacting with the first metal pad 1310 to an end of the first via 1400 for contacting with the second metal pad 1231. In other words, an area of a cross-section of the first via 1400 at the end for contacting with the first metal pad 1310 is larger than an area of a cross-section of the first via 1400 at the end for contacting with the second metal pad 1231 of the first via 1400.

As shown in FIG. 2, the first metal pad 1310 has a second diameter D2. The second diameter D2 of the first metal pad 1310 is gradually decreased in a direction from a top end of the first metal pad 1310 as shown in FIG. 2 to a bottom end of the first metal pad 1310 for contacting with the first via 1400. The first metal pad 1310 further has a first overlap window W1. An overlap window is a critical dimension indicating an alignment accuracy of a pad and corresponding via, such as the first metal pad 1310 and the first via 1400.

As shown in FIG. 2, the second metal pad 1231 has a third diameter D3. The third diameter D3 of the second metal pad 1231 is gradually decreased in a direction from a top end of the second metal pad 1231 for contacting with the first via 1400 to a bottom end of the second metal pad 1231. The second metal pad 1231 further has a second overlap window W2 for alignment accuracy of the first via 1400 and the second metal pad 1231.

As shown in FIG. 2, the via 1241 as a portion of a Damascus structure has a fourth diameter D4 and a height H2. The fourth diameter D4 of the via 1241 is gradually decreased in a direction from a top end of the via 1241 for contacting with the second metal pad 1231 to a bottom end of the via 1241 for contacting with the metal pad 1233. In other words, an area of a cross-section of the via 1241 at the top end for contacting with the second metal pad 1231 is larger than an area of a cross-section of the via 1241 at the bottom end for contacting with the metal pad 1233. With respect to the via 1241, the second metal pad 1231 as a portion of the Damascus structure further has a third overlap window W1’ for alignment accuracy of the via 1241 and the second metal pad 1231.

As shown in FIG. 2, the metal pad 1233 has a fifth diameter D5. The fifth diameter D5 of the metal pad 1233 is gradually decreased in a direction from a top end of the metal pad 1233 for contacting with the via 1241 to a bottom end of the metal pad 1233. The metal pad 1233 further has a fourth overlap window W2’ for alignment accuracy of the via 1241 and the metal pad 1233.

As shown in FIGS. 1A and 2, since the first via 1400 extends through two metal layers in the layers 1211 and 1212, there is no need to arrange metal pads in the two metal layers in the layers 1211 and 1212 for contacting with vias. Thereby, the area for wiring in the semiconductor structure 1000 A is reduced, compared with the stacking of Damascus structures. The area reduction for wiring further reduces an interference among metal lines, pads, and vias in the semiconductor structure 1000 A. In some embodiments, the saved area for wiring may be further used for arranging more metal lines in the metal layers of the wiring layer 1200, to increase the density of the metal lines.

Further, since the height H1 of the first via 1400 is greater than a thickness between the bonding layer 1300 and an adjacent metal layer or a thickness between two adjacent metal layers in the wiring layer 1200, for example, the height H1 is greater than the height H2, the first diameter D1 of the first via 1400 at a bottom end for contacting with the second metal pad 1231 may be smaller than that of a via extending between the bonding layer 1300 and an adjacent metal layer or between two adjacent metal layers, such as the fourth diameter D4 at bottom end of the via 1241 in the Damascus structure. Thereby, with respect to the same overlap windows W2 and W2’, the third diameter D3 of the second metal pad 1231 at the top end for contacting with the first via 1400 may be smaller than that of the metal pad 1233 for contacting with the via 1241 in the Damascus structure. Thus, the area for wiring in the semiconductor structure 1000A may be further reduced, as compared with the stacking of Damascus structures.

With the above first via 1400 according to the embodiments of the present disclosure, the number of connection points between vias and metal pads is reduced (since the first via 1400 extends through at least one metal layer). This may improve the reliability of the wiring in the semiconductor structure 1000 A and may reduce the cost and the complexity of manufacturing the semiconductor structure 1000 A. The first via 1400 may include at least one of tungsten, titanium or aluminum. In a case that the first via 1400 includes tungsten, the reliability of wiring in the semiconductor structure 1000 A can be further improved.

It can be understood that, although FIG. 1A illustrates that the first via 1400 extends through two metal layers in the layers 1211 and 1212, respectively, the first semiconductor structure may include a first via extending through more or less than two metal layers of the wiring layer 1200. For example, FIG. 1B illustrates another example of a first semiconductor structure 1000B, which includes another first via 1400’ extending through four metal layers, which are in layers 1211, 1212, 1213, and 1214, respectively, and extending between another second metal pad 1231’ of a metal layer in the layer 1215 and another first metal pad 1310’ in the bonding layer 1300. Further, the another second metal pad 1231’ may be electrically connected to a via 1242 extending in the dielectric layer of the layer 1215, and the another second metal pad 1231’ and the via 1242 form another Damascus structure. FIG. 1C illustrates yet another example of a first semiconductor structure 1000C, which includes yet another first via 1400’’ extending through one metal layer in the layer 1211, and extending between yet another second metal pad 1231’’ of a metal layer in the layer 1212 and yet another first metal pad 1310’’ in the bonding layer 1300. Further, the yet another second metal pad 1231’’ may be electrically connected to a via 1243 extending in the dielectric layer of the layer 1212, and the yet another second metal pad 1231’ and the via 1243 form yet another Damascus structure.

In other words, in some embodiments, the first via may extend through a plurality of metal layers of the metal layers in the wiring layer 1200. In some further embodiments, the first via may extend through one metal layer of the metal layers in the wiring layer 1200. It can be understood that although FIGS. 1A-1C show only three first vias 1400, 1400’, and 1400’’, there could be a plurality of first vias in the first semiconductor structure. Further, it can be understood that the relative positions of the first vias and the Damascus structures shown in FIGS. 1A-1C are only examples, and in some embodiments, at least one of the first vias may be arranged as not directly over a Damascus structure, e.g., the Damascus structure may not be arranged directly under the first via.

In some embodiments, in addition to the first via 1400, 1400’, or 1400’’, the first semiconductor structure may further include a second via. The second via may extend between a third metal pad of a second one of the metal layers of the wiring layer 1200 and a fourth metal pad of the bonding layer 1300, without extending through the metal layers. For example, FIG. 3 illustrates a schematic cross-section view of an example of such first semiconductor structure 3000 including the first via and the second via of the semiconductor device according to the embodiments of the present disclosure. As shown in FIG. 3, the first semiconductor structure 3000 may further include a second via 1500, and the second via 1500 extends between a third metal pad 1232 of a second one (e.g., a metal layer in the layer 1211 as shown in FIG. 3) of the metal layers and a fourth metal pad 1320 of the bonding layer 1300, without extending through the metal layers. In some embodiments, the second via 1500 may include metal material which is the same as that of the first via 1400, 1400’, or 1400’’. In some further embodiments, the second via 1500 may include metal material which is different from that of the first via 1400, 1400’, or 1400’’.

In some embodiments, in addition to the first via 1400, 1400’, or 1400’’ and the second via 1500, the first semiconductor structure may further include a third via. The third via may extend between two metal pads of two adjacent ones of the metal layers of the wiring layer 1200. For example, the third via may be a portion of the wiring layer 1200, may be a portion of a Damascus structure, and may be formed during the forming of the wiring layer 1200. For example, the via 1241 shown in FIGS. 1A-1C is a such third via. The via 1241 extends between two metal pads 1231 and 1233 of two adjacent metal layers in the layers 1213 and 1214. Further, the vias 1242 and 1243 shown in FIGS. 1A-1C each may also be a such third via, and one corresponding metal pad thereof is not shown in FIGS. 1A-1C.

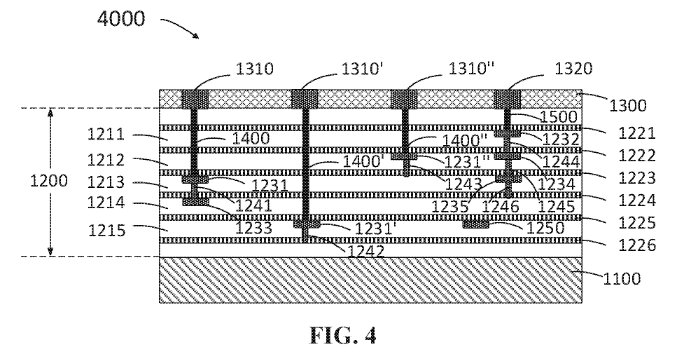

In the wiring layer 1200, there may be a plurality of third vias and a plurality of corresponding Damascus structures, and some of the Damascus structures may be stacked vertically with each other (such as stacked directly or not directly over one another), in order to electrically connect two metal layers which are not adjacent to each other. FIG. 4 illustrates a schematic cross-section view of an example of such first semiconductor structure 4000 according to the embodiments of the present disclosure. As shown in FIG. 4, the first semiconductor structure 4000 may further include a third via 1244, and the third via 1244 extends between two metal pads (e.g., two metal pads 1232 and 1234 shown in FIG. 4) of two adjacent ones (e.g., two metal layers in the layers 1211 and 1212 respectively) of the metal layers in the wiring layer 1200. The metal pad 1232 and the third via 1244 may be considered as a Damascus structure. In the wiring layer 1200, the adjacent metal layers may be electrically connected with each other by using the Damascus structure. Further, the vias 1245 and 1246 may also be third vias, and one corresponding metal pad of via 1246 is not shown in FIG. 4.

As shown FIG. 4, a Damascus structure formed by the third metal pad 1232 and the via 1244, a Damascus structure formed by the metal pad 1234 and the via 1245, and a Damascus structure formed by the metal pad 1235 and the via 1246, are stacked vertically with each other, to electrically connect the metal layer in the layer 1211 and the metal layer in the layer 1214. It can be understood that, although these Damascus structures in FIG. 4 are shown as stacked directly over one another, in some other embodiments, they may be stacked not directly over one another as described above. It can be understood that, in addition to the third via(s) and above metal pads, the wiring layer 1200 may further include other element, such as a metal pad 1250 for connecting with a power supply unit or the like, as shown in FIG. 4.

Referring to FIGS. 2 and 4, it can be seen that, the first via 1400 has a depth-to-width ratio greater than a depth-to-width ratio of the third via (for example, any one of the vias 1241-1246). The depth-to-width ratio of the first via 1400 may be a ratio of the height H1 of the first via 1400 to the first diameter D1 of a selected cross-section of the first via 1400, such as a cross-section of a top end (or a bottom end) of the first via 1400 as shown in FIG. 2. The depth-to-width ratio of the third via may be a ratio of a height of the third via (for example, the height H2 of the via 1241) to a diameter of a corresponding cross-section of the third via (for example, the corresponding diameter D2 of the via 1241), such as a cross-section of a top end (or a bottom end) of the third via as shown in FIG. 4. It can be understood that the diameters for obtaining the depth-to-width ratios of the first via 1400 and the third via 1241 are not limited to the above examples, as long as the two diameters for obtaining the depth-to-width ratios of the first via 1400 and the third via 1241 are selected from corresponding cross-sections of the first via 1400 and the third via. Further, although the diameters are used for obtaining the depth-to-width ratios in the above embodiments, the depth-to-width ratios can be obtained by parameters other than the diameters in dependent on the shapes of the first and third vias. For example, the parameters may be the widths of the corresponding cross-sections of the first and third vias.

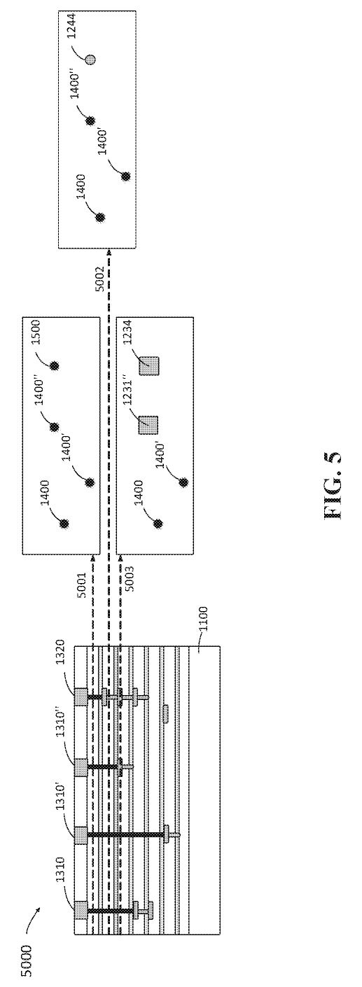

In some embodiments, the metal material of the third via(s) may be different from the metal material of the first via 1400. Thereby, a cross-section (e.g., a transverse cross-section) of the wiring layer 1200 may include a part of the third via and a part of the first via 1400, 1400’ or 1400’’, e.g., include different materials, which is shown in the following FIG. 5. In some further embodiments, the third via may include copper, and the first via 1400 may include tungsten. In some further embodiments, the metal pads 1310, 1310’, 1310’’ and 1320 of the bonding layer 1300 each may include at least one of copper, tungsten, titanium or aluminum, and the metal pads 1231, 1231’, 1231’’, 1232, 1233, and 1250 may include copper.

FIG. 5 illustrates transverse cross-section views of an example of such the first semiconductor structure 5000 according to the embodiments of the present disclosure. In FIG. 5, three transverse cross-section views of the first semiconductor structure 5000 are illustrated, and the three transverse cross-section views are indicated by arrows 5001, 5002, and 5003, respectively. The transverse cross-section view indicated by arrow 5001 is taken from the top dielectric layer of the wiring layer 1200, and this transverse cross-section view includes a part of the first via 1400, a part of the first via 1400’, a part of the first via 1400’’, and a part of the second via 1500.

The transverse cross-section view indicated by arrow 5002 is taken from a dielectric layer in the layer 1211 of the wiring layer 1200, and this transverse cross-section view includes a part of the first via 1400, a part of the first via 1400’, a part of the first via 1400’’, and a part of the third via 1244, e.g., this transverse cross-section view includes different materials, such as tungsten included in the first vias 1400, 1400’ and 1400’’ and copper included in the third via 1244.

The transverse cross-section view indicated by arrow 5003 is taken from a metal layer in the layer 1212 of the wiring layer 1200, and this transverse cross-section view includes a part of the first via 1400, a part of the first via 1400’, a part of the second metal pad 1231’’, and a part of the metal pad 1234, e.g., this transverse cross-section view also includes different materials, such as tungsten included in the first vias 1400 and 1400’ and copper included in the metal pads 1231’’ and 1234.

The transverse cross-section views indicated by arrows 5002 and 5003 of the present application are different from that of a conventional wiring layer. In the conventional wiring layer, the stacked Damascus structures are used for electrically connecting the metal layers, which are not adjacent to each, and thus for any transverse cross-section view thereof, the transverse cross-section view only includes the metal material of the third via or only includes the metal material of the metal pad, it does not include different metal materials.

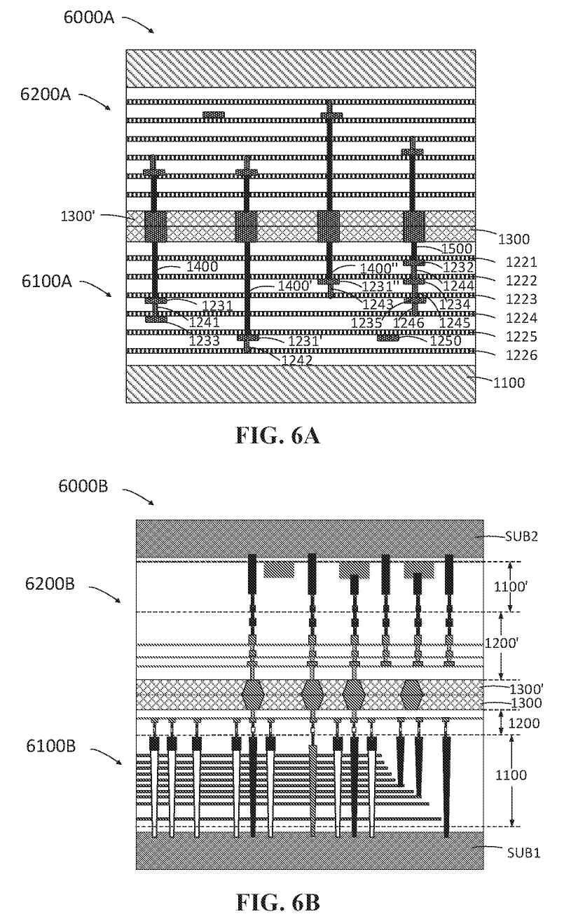

In a case that the first semiconductor structure is arranged as above, the bonding layer 1300 of the first semiconductor structure can be bonded with another bonding layer of the second semiconductor structure to form the semiconductor device. FIG. 6A is a schematic cross-section view of an example of a semiconductor device 6000A with two semiconductor structures 6100A and 6200A bonded with each other according to the embodiments of the present disclosure. As shown in FIG. 6, the first semiconductor structure 6100A and the second semiconductor structure 6200A have been bonded with each other by the bonding layer 1300 of the first semiconductor structure 6100A and another bonding layer 1300’ of the second semiconductor structure 6200A. The first semiconductor structure 6100A may be any one of the first semiconductor structures 1000A, 1000B, 1000C, 3000, 4000 and 5000 as shown in FIGS. 1A-1C and 3-5. The second semiconductor structure 6200A may have a structure similar to that of the first semiconductor structure 6100A as shown in FIG. 6A.

FIG. 6B is a schematic cross-section view of another example of a semiconductor device 6000B with two semiconductor structures 6100B and 6200B bonded with each other according to the embodiments of the present disclosure. As shown in FIG. 6B, the first semiconductor structure 6100B may be a memory chip, and the second semiconductor structure 6200B may be a peripheral chip for the memory chip. The first semiconductor structure 6100B includes the function layer 1100, the wiring layer 1200, and the bonding layer 1300, as described above. The function layer 1100 is arranged on a first substrate SUB1. The second semiconductor structure 6200B may include another function layer 1100’, another wiring layer 1200’, and another bonding layer 1300’. The function layer 1100’ is arranged on a second substrate SUB2. The first semiconductor structure 6100B and the second semiconductor structure 6200B have been bonded with each other by the bonding layer 1300 of the first semiconductor structure 6100B and another bonding layer 1300’ of the second semiconductor structure 6200B. The first semiconductor structure 6100B may be any one of the first semiconductor structures 1000A, 1000B, 1000C, 3000, 4000, 5000, and 6000A as shown in FIGS. 1A-1C and 3-6A. The second semiconductor structure 6200B may have a structure similar to that of the first semiconductor structure 6100B as shown in FIG. 6B.

In the embodiments shown in FIGS. 6A-6B, the bonding of the bonding layers 1300 and 1300’ may form a one-piece bonding structure without an interface between the bonding layer 1300 and another bonding layer 1300’. In some further embodiments, the bonding of the bonding layers 1300 and 1300’ may form a bonding structure with an interface between the bonding layer 1300 and the another bonding layer 1300’.

It can be understood that, in the above FIGS. 1A-6B, the thicknesses of the layers, the number of the layers, the number of the vias, the number of the metal pads, and other arrangements, of the first and second semiconductor structures are only examples, these arrangements may be implemented differently from those shown in FIGS. 1A-6B, according to actual requirements.

It can be understood that the semiconductor device 6000B shown in FIG. 6B may pad-out at any one of the side of the first semiconductor structure 6100B and the side of the second semiconductor structure 6200B. In this case, any one of the first substrate SUB1 and the second substrate SBU2 can be thinned or removed. Further, the semiconductor device 6000B shown in FIG. 6B may be formed as one memory device in a High Bandwidth Memory (HBM) device.

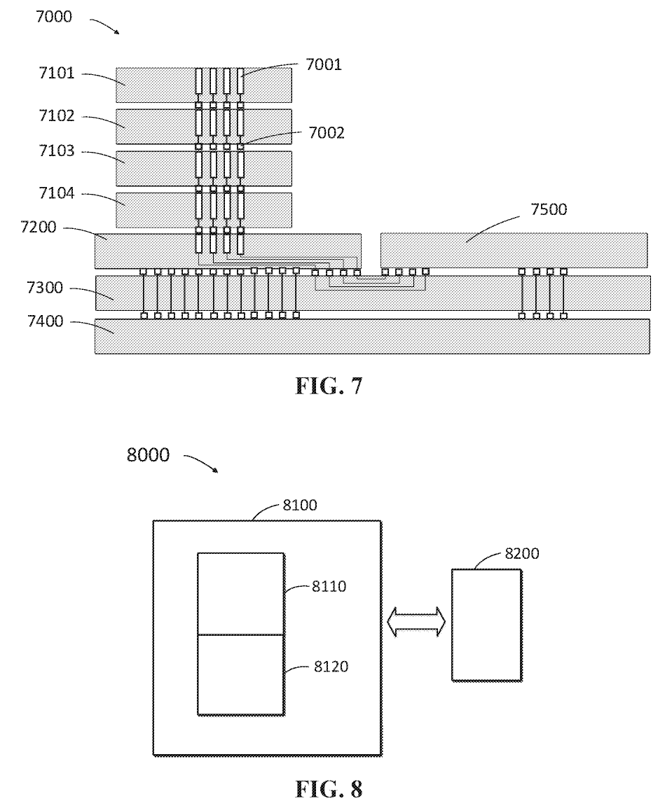

FIG. 7 is a schematic cross-section view of a HBM device 7000 including the semiconductor device 6000B according to the embodiments of the present disclosure. The HBM device 7000 may employ stacked memory devices 6000B to achieve efficient data transmission and access. The HBM device 7000 may have small power consumption with a small form factor and may achieve a relatively high bandwidth. Therefore, the HBM device has been used in various application fields, such as, but not limit to, a high-performance graphics accelerator, a network device, a high-performance data center, an artificial intelligence (AI) and machine learning (ML) training, an artificial intelligence inference, a supercomputer, and so on.

As shown in FIG. 7, the HBM device 7000 includes a plurality of memory dies 7101, 7102, 7103 and 7104 in FIG. 7. The memory dies 7101-7104 each may include a plurality of memory devices 6000B of FIG. 6B, and the memory dies 7101-7104 are stacked in a vertical direction. The HBM device 7000 further includes a logic chip die 7200, which includes logic chips; an intermediate interposer 7300; a package substrate 7400; and a computing die 7500, such as CUP/GPU/SoC die. The memory dies 7101-7104, the logic chip die 7200, the intermediate interposer 7300 and the package substrate 7400 are stacked in the vertical direction. In some embodiments, TSVs 7001 and microbumps 7002 may be used for the connections among the memory dies 7101-7104, the logic chip die 7200, the intermediate interposer 7300, the package substrate 7400 and the computing die 7500. For example, the logic chip die 7200 may be connected to the package substrate 7400 via the intermediate interposer 7300, by means of microbumps 7002. Further, the computing die 7500 may be connected to the logic chip die 7200 and the package substrate 7400 via the intermediate interposer 7300, by means of microbumps 7002. Thereby, an SiP system is formed.

It should be noted that, the terms “dies” and “die” can be used interchangeably in the present disclosure. The plurality of memory dies 7101-7104 may be bonded together using the above direct bonding technologies. In some embodiments, some of the memory dies 7101-7104 may be thinned (e.g., the first substrate SBU1 and the second substrate SBU2 shown in FIG. 6B may be thinned), thereby increasing the memory density and capacity of the HBM device 7000. In some embodiments, one of the memory dies 7101-7104 may be thicker than the others of the memory dies 7101-7104, so as to replace carrier wafers to provide support to the others of the memory dies 7101-7104, during the manufacturing process of the memory dies 7101-7104. The memory dies 7101-7104 may be coupled to each other, and may be coupled to the logic chip die 7200 through the shown contact structures extending into the stacked memory dies 7101-7104. By bonding the memory dies 7101-7104, the logic chip die 7200, the computing die 7500, the interposer 7300, the package substrate 7400, etc., by means of the shown contact structures, a higher interconnection density among different dies in the HBM device 7000 may be achieved, and the bandwidth and data transmission speed of the HBM device 7000 may be increased. The contact structure for bonding may be bump bonding, hybrid bonding, direct bonding, or any other bonding means which may bond two different dies.

In some embodiments, one or more memory devices 6000B included in at least one of the memory dies 7101-7104 may include DRAM devices. In some further embodiments, one or more memory devices 6000B included in at least one of the memory dies 7101-7104 may include NAND flash memory devices.

The logic chip die 7200 (also referred to as a base die, a logic die or a buffer die) may include a buffer circuit and a test logic unit for the memory dies 7101-7104. The logic chip die 7200 may be configured to provide a physical (PHY) layer communication protocol (e.g., IEEE-1500) between the memory dies 7101-7104 and the computing die 7500. The logic chip die 7200 may be configured to transfer data between the memory dies 7101-7104 and the computing die 7500 based on a control command and an address from the computing die 7500.

The computing die 7500 may be a logic device and may include at least one processor of an electronic device, such as a central processing unit (CPU), a graphics processing unit (GPU), an application specific integrated circuit (ASIC), or a system on a chip (SoC), such as an application processor (AP). The computing die 7500 may be configured to transmit data to or receive data from the memory dies 7101-7104. The computing die 7500 may be coupled to the logic chip die 7200 via an interface therebetween. This interface may include connections provided by bonding contacts (e.g., microbumps) or the interposer 7300. In some embodiments, this interface may include other connections provided by any suitable combination of the above contact structures.

The HBM device 7000 may further include an external host die coupled to the computing die 7500 via an interface. For example, external host die may be a computer, and then the computing die 7500 may be a CPU of the computer. In this embodiment, this interface may include a connection provided by a motherboard of the computer coupled to the CPU. In some other embodiments, the external host die may be a graphics card, and then the computing die 7500 may be a GPU of the graphics card. In this embodiment, the above interface may include a connection provided by a printed circuit board (PCB) of the graphics card coupled to the GPU.

The HBM device 7000 may further include a memory controller (also referred to as a controller circuit) coupled to memory dies 7101-7104. In some embodiments, the memory controller may be located in the computing die 7500. According to the embodiments of the present disclosure, the memory controller may include conductive interconnects passing through a cover layer which is in contact with a conductive pad in a conductive pad layer, and the memory controller may be coupled to the memory dies 7101-7104 via at least one of the conductive interconnects. The memory controller may be configured to control the memory dies 7101-7104. For example, the memory controller may be configured to operate a channel structure via a word line. The memory controller may manage data stored in the memory dies 7101-7104 and communicate with the computing die 7500.

The memory controller may communicate with an external device (e.g., the computing die 7500) according to a specific communication protocol. For example, the memory controller may communicate with the external device through at least one of various interface protocols, such as a CXL protocol, a USB protocol, an MMC protocol, a peripheral component interconnect (PCI) protocol, a PCI-Express (PCIe or PCI-e) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a FireWire protocol, and so on.

In some embodiments, the logic chip die 7200 may also include a control circuit configured to control the memory dies 7101-7104. The control circuit may be coupled to the memory dies 7101-7104, for example, through contact structures, interconnect layers of the memory dies 7101-7104, and conductive bonding contacts.

As described above, the logic chip die 7200 may be coupled to the computing die 7500 through the interposer 7300. The interposer 7300 has a top surface. The vias in the logic chip die 7200 may be connected to conductive terminals on the top surface of the interposer 7300. The computing die 7500 may also be connected to conductive terminals on the top surface of the interposer 7300. The conductive terminals may be coupled via conductive lines in the logic chip die 7200 and the interposer 7300. Some conductive terminals may be coupled to an external device (e.g., external host die). In some embodiments, the conductive terminals may be microbumps. It should be understood that in practice, the logic chip die 7200, the computing die 7500, and interposer 7300 may be integrated together using any suitable packaging technology (including, but not limited to, Chip-on-Wafer-on-Substrate (CoWoS)).

In some embodiments, the memory dies 7101-7104 may have a reduced thickness (in the vertical direction) by thinning their substrates. The topmost memory die 7101 (e.g., the one of the memory dies 7101-7104 which is farthest from the logic chip die 7200) may not be thinned. Therefore, the thickness of each of the memory dies 7102-7104 may be less than the thickness of the memory die 7101. The thickness of each of the memory dies 7102-7104 may be within any suitable range (for example, between 3μm and 20μm, or any other range). In this way, even if the stack of memory dies 7101-7104 is inverted in a processing step, the topmost memory die 7101 may provide support due to its thickness.

Although in FIG. 7, four memory dies 7101-7104 are shown in the stack, the embodiments of present disclosure may be applied to a stack with any suitable number of memory dies (e.g., 2, 5, 8, or other numbers). The number of memory dies may be determined based on factors including for example a technical constraint, a thermal consideration, a signal integrity and interference, a physical size and application, a cost and yield, a reliability consideration, and so on.

In some embodiments, each of the memory dies 7101-7104 may include a fully functional electronic circuit (e.g., a microprocessor, a memory, a sensor, or any other suitable type of integrated circuit) and may be encapsulated in a protective package.

In some embodiments, the memory dies 7101-7104 may be from a semiconductor wafer. The semiconductor wafer may include a plurality of memory dies 7101-7104 or memory devices manufactured by a plurality of processes, such as depositing multiple layers of various materials, and etching the semiconductor wafer according to a complex pattern defined by the chip design. After the processes are completed, the semiconductor wafer is diced into individual slices. Each individual slice (which may also be referred to as a die) may include a fully functional electronic circuit, which may be a microprocessor, an HBM, a sensor, or any other suitable type of integrated circuit. In some embodiments, each individual die may be enclosed in a protective package, which provides physical support, to protect the die from the effect of environment, and provides connections to an external device or system (for example, through pins or solder balls).

FIG. 8 is a schematic block diagram of an example of a system 8000 according to the embodiments of the present disclosure. As shown in FIG. 8, the system 8000 includes a memory 8100 and a controller 8200, which is configured to control the memory 8100. The memory 8100 includes a first semiconductor structure 8110 and a second semiconductor structure 8120. The first semiconductor structure 8110 may be any one of the first semiconductor structures 1000A, 1000B, 1000C, 3000, 4000, 5000, 6000A, and 6000B shown in FIGS. 1A-1C and 3-6B. The second semiconductor structure 8120 may be the second semiconductor structure 6000A or 6000B as shown in FIGS. 6A or 6B.

In particular, a first semiconductor structure 8100 may include a function layer, such as the function layer 1100 as shown in FIGS. 1A-1C and 3-6B. The first semiconductor structure 8100 may further include a wiring layer arranged on the function layer 1100, and the wiring layer includes metal layers, such as the wiring layer 1200 as shown in FIGS. 1A-1C and 3-7. The first semiconductor structure 8100 may further include a bonding layer arranged on the wiring layer 1200, and the bonding layer includes a first metal pad, such as the bonding layer 1300 as shown in FIGS. 1A-1C and 3-6B, which includes the first metal pad 1310, 1310’, or 1310’’. The first semiconductor structure 8100 may further include a first via extending through at least one metal layer of the metal layers and extending between a second metal pad of a first one of the metal layers and the first metal pad, such as the first via 1400, 1400’ or 1400’’ as shown in FIGS. 1A-6A.

The second semiconductor structure 8120 is bonded with the first semiconductor structure 8110 by the bonding layer 1300 of first semiconductor structure 8100 and the another bonding layer (such as the another bonding layer 1300’ shown in FIGS. 6A-6B) of the second semiconductor structure 8120. In some embodiments, the first semiconductor structure 8110 may be one of a memory chip or a peripheral chip for the memory chip. In some embodiments, the second semiconductor structure 8120 may be the other one of the memory chip or the peripheral chip. It can be understood that the memory 8100 including the first and second semiconductor structures 8110 and 8120 may have the same structures and benefits with the first and second semiconductor structures as shown in FIGS. 1A-6B, which will not be repeated herein.

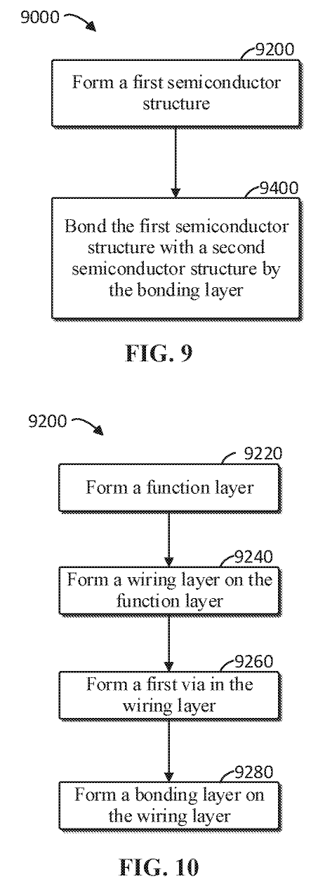

FIG. 9 is a schematic flowchart of an example of a method 9000 for manufacturing a semiconductor device according to the embodiments of the present disclosure. The method 9000 may be performed by any processor or controller which may control a device such as a lithography machine to perform the following processes.

In FIG. 9, at block 9200, a first semiconductor structure is formed. In some embodiments, the first semiconductor structure may be any one of the first semiconductor structures 1000A, 1000B, 1000C, 3000, 4000, 5000, 6000A, and 6000B as shown in FIGS. 1A-1C and 3-6B. In some embodiments, the first semiconductor structure may be one of a memory chip and a peripheral chip for the memory chip.

At block 9400, the first semiconductor structure is bonded with a second semiconductor structure by a bonding layer of the first semiconductor structure. In some embodiments, block 9400 may include bonding the first semiconductor structure with a second semiconductor structure by another bonding layer of the second semiconductor structure and the bonding layer of the first semiconductor structure. In some embodiments, the second semiconductor structure may be the second semiconductor structure 6200A or 6200B as shown in FIGS. 6A or 6B. In some embodiments, the second semiconductor structure may be the other one of the memory chip or the peripheral chip.

Hereafter, the process for forming the first semiconductor structure will be described in detail. It can be understood that the second semiconductor structure can be formed in a similar way. FIG. 10 is a schematic flowchart of an example of the process for forming the first semiconductor structure of FIG. 9 according to the embodiments of the present disclosure.

In FIG. 10, at block 9220, a function layer is formed. As shown in FIG. 11, which is a schematic cross-section view showing a forming of the function layer according to the embodiments of the present disclosure, the function layer 1100 is formed.

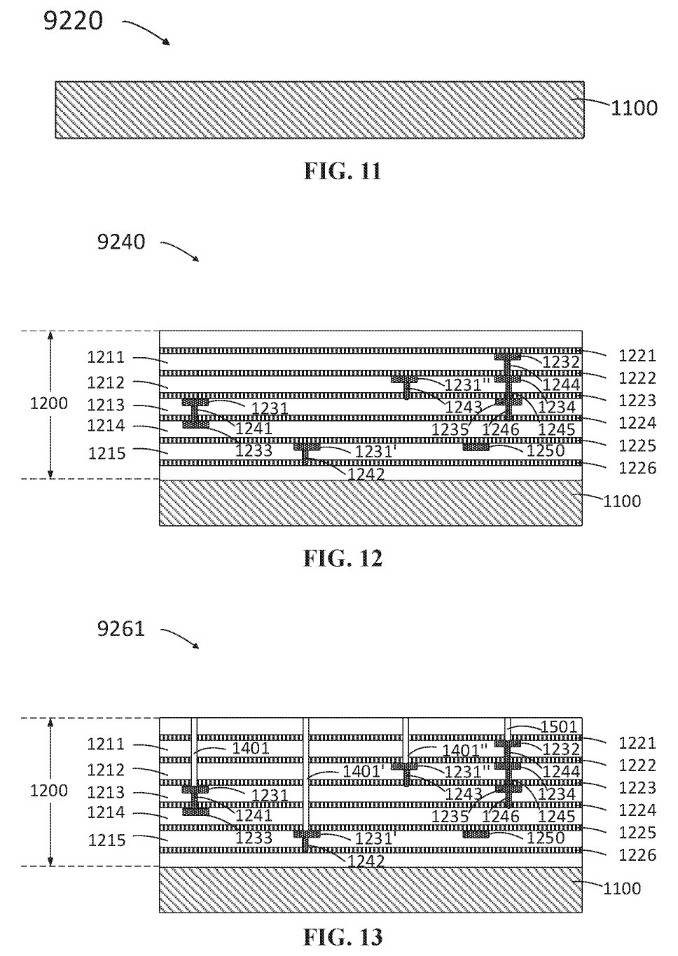

At block 9240 of FIG. 10, a wiring layer is formed on the function layer 1100, and the wiring layer includes metal layers. As shown in FIG. 12, which is a schematic cross-section view showing a forming of the wiring layer according to the embodiments of the present disclosure, the wiring layer 1200 is formed on the function layer 1100. The wiring layer 1200 includes the layers 1211-1215, each of which may include a metal layer as described above. In some embodiments, the wiring layer 1200 may further include metal pads 1231, 1231’, 1231’’, 1232-1235, and 1250, which may be the same as those shown in FIGS. 1-6B. In some embodiments, the wiring layer 1200 may further include a third via extending between two metal pads 1232 and 1233 of two adjacent ones of the metal layers, such as the vias 1241-1246, which may be the same as those shown in FIGS. 1-6B. In some further embodiments, the wiring layer 1200 may further include the layers 1221-1226 as described above. The details of the wiring layer 1200 have been described above, which will not be repeated herein.

At block 9260 of FIG. 10, a first via is formed in the wiring layer 1200. In some embodiments, forming the first via in the wiring layer 1200 at block 9260 may include etching the wiring layer 1200 to form a first hole. Block 9260 may further include depositing, by a PVD or CVD process, metal material into the first hole, to form the first via.

As shown in FIG. 13, which is a schematic cross-section view showing a forming 9261 of holes in the wiring layer 1200 according to the embodiments of the present disclosure, the first holes 1401, 1401’ and 1401’’ are etched in the wiring layer 1200.

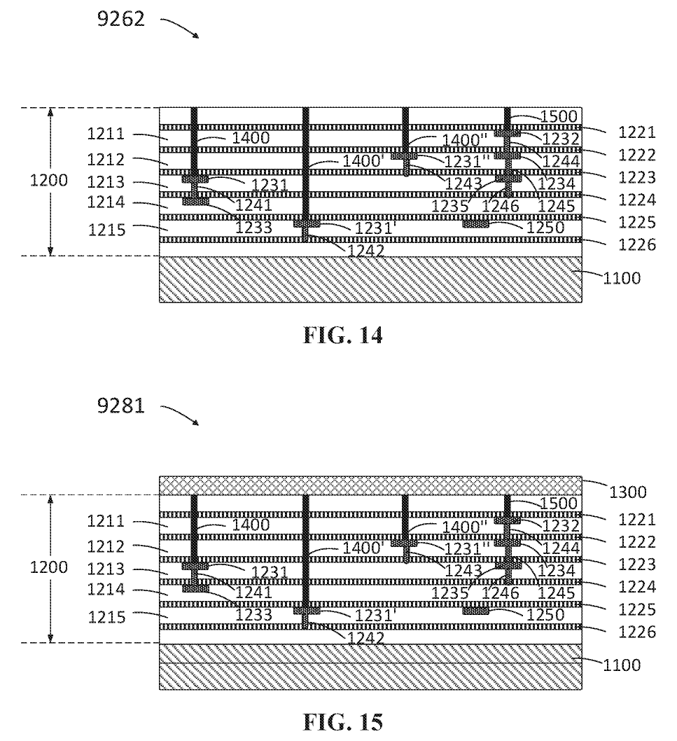

As shown in FIG. 14, which is a schematic cross-section view showing a forming 9262 of vias in the wiring layer 1200 according to the embodiments of the present disclosure, the metal material is deposited into the first holes 1401, 1401’ and 1401’’, to form the first vias 1400, 1400’, and 1400’’.

In some embodiments, the first via 1400, 1400’, or 1400’’ may have a depth-to-width ratio greater than a depth-to-width ratio of the third via, as described above. In some embodiments, the metal material of the third via may be different from the metal material of the first via 1400, 1400’ or 1400’’. In some embodiments, a cross-section of the wiring layer 1200 may include a part of the third via and a part of the first via 1400, 1400’, or 1400’’, as shown in FIG. 5. In some embodiments, the third via may include copper. In some embodiments, the first via 1400, 1400’, or 1400’’ may include at least one of tungsten, titanium, or aluminum.

In some embodiment, during or before or after the forming of the first via 1400, 1400’ or 1400’’, the process 9200 may further include forming a second via in the wiring layer 1200. The second via may extend between a third metal pad of a second one of the metal layers and a fourth metal pad (which will be formed at block 9280 hereafter) of the bonding layer without extending through the metal layers. For example, as shown in FIG. 13, a hole 1501 is further formed, and the hole 1501 extends between a third metal pad 1232 of a metal layer in layer 1211 and a top surface of the wiring layer 1200. As shown in FIG. 14, metal material, which is the same as or different from the metal material for forming the first via, is deposited into the hole 1501, to form the second via 1500.

At block 9280 of FIG. 10, a bonding layer is formed on the wiring layer 1200, and the bonding layer includes a first metal pad. In some embodiments, forming the bonding layer on the wiring layer 1200 at block 9280 may include depositing insulation material on the wiring layer 1200 to form a insulation layer. Block 9280 may further include etching the insulation layer to form a second hole passing through the insulation layer and directly over the first via. Block 9280 may further include filling the second hole with metal material to form the first metal pad. Block 9280 may further include polishing, by a CMP process, the insulation layer with the first metal pad, to form the bonding layer.

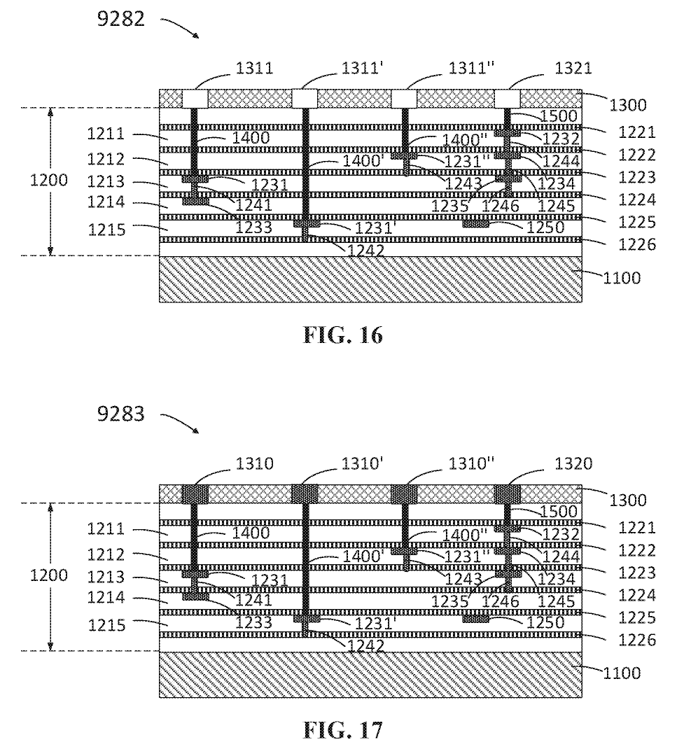

As shown in FIG. 15, which is a schematic cross-section view showing a forming 9281 of the insulation layer on the wiring layer 1200 according to the embodiments of the present disclosure, the bonding layer 1300 is formed on the wiring layer 1200 by depositing insulation material on the wiring layer 1200. As shown in FIG. 16, which is a schematic cross-section view showing a forming 9282 of holes in the bonding layer 1300 according to the embodiments of the present disclosure, second holes 1311, 1311’ and 1311’’ are etched in the bonding layer 1300. The second holes 1311, 1311’, and 1311’’ pass through the bonding layer 1300 and are directly over the corresponding first vias 1400, 1400’, and 1400’’. Further, in the embodiment that the second via 1500 is formed, a hole 1321 is further etched in the bonding layer 1300 (e.g., an insulation layer), and the hole 1321 passes through the bonding layer 1300 and is directly over the second via 1500.

As shown in FIG. 17, which is a schematic cross-section view showing a forming 9283 of metal pads and the bonding layer according to the embodiments of the present disclosure, metal material is filled into the second holes 1311, 1311’, and 1311’’ to form the first metal pads 1310, 1310’, and 1310’’. In some further embodiments, metal material is also filled into the hole 1321 to form the fourth metal pad 1320. Then, the bonding layer 1300 with the first metal pads 1310, 1310’, and 1310’’ (and the fourth metal pad 1320) is polished by a CMP process, and the polished insulation layer is the bonding layer 1300.

A non-transitory computer readable storage medium is further provided in an embodiment of the disclosure. The computer storage medium stores a computer program which, when executed by a processor, causes the processor to implement the method for manufacturing a semiconductor device according to the above embodiments of the present disclosure.

The above computer-readable medium of the disclosure may be a computer-readable signal medium, a computer-readable storage medium, or any combination of the above. The computer-readable storage medium may be, for example, an electronic, magnetic, optical, electromagnetic, infrared, or semiconductor system, apparatus, or device, or any combination of the above. Instances of the computer-readable storage medium may include: a portable computer magnetic disc, a hard disc, an RAM, an ROM, an erasable programmable read-only memory (EPROM) or a flash memory, an optical fiber, a portable compact disc read-only memory (CD-ROM), an optical storage device, and a magnetic storage device that are each electrically connected through one or more wires, or any suitable combination of the above. In the disclosure, the computer-readable storage medium may be any tangible medium that includes or stores a program. The program may be used by or in combination with an instruction execution system, apparatus, or device. In the disclosure, however, the computer-readable signal medium may include a data signal propagated in a baseband or as part of a carrier wave, having a computer-readable program code carried thereon. Such a propagated data signal may take various forms including an electromagnetic signal, an optical signal, or any suitable combination of the above. The computer-readable signal medium that may also be any computer-readable medium except for the computer-readable storage medium, may transmit, propagate, or transfer a program to be used by or in combination with the instruction execution system, apparatus, or device. The program code included in the computer-readable medium may be transferred via any suitable medium, including a wire, an optic cable, a radio frequency (RF), etc., or any suitable combination of the above.

The computer program codes configured to execute operations of the disclosure can be written in one or more programming languages or their combinations. The above programming languages include object-oriented programming languages, such as Java, Smalltalk, and C++, and conventional procedural programming languages, such as “C” language. The program code can be executed on a user’s computer in all or in part, executed as an independent software package, executed on a user’s computer in part and executed on a remote computer in part, or executed on a remote computer or a server in all. In a case involving the remote computer, the remote computer can be connected to the user’s computer through any kind of network, including the LAN or the WAN, or can be connected to an external computer (for example, through the Internet by means of an Internet service provider).

The flowcharts and block diagrams in the accompanying drawings illustrate possibly implementable system architectures, functions, and operations of the system, method, and computer program product according to various embodiments of the disclosure. In this regard, each block in the flowcharts or the block diagrams can indicate a module, a program segment, or a code segment, which includes one or more executable instructions configured to implement specified logic functions. It should also be noted that in some alternative embodiments, the functions noted in the blocks can also occur in an order other than those noted in the accompanying drawings. For example, two blocks represented in succession can in fact be executed substantially in parallel or in a reverse order sometimes, depending on the functions involved. It should also be noted that each block in the block diagrams and/or the flowcharts and combinations of blocks in the block diagrams and/or the flowcharts can be implemented through specific hardware-based systems that execute the specified functions or operations, or combinations of specific hardware and computer instructions.

The unit involved in the embodiment of the disclosure can be implemented through software or hardware. The name of the unit is not intended to define the unit itself under one circumstance. For example, a first acquisition unit can also be described as “a unit that acquires at least two Internet protocol addresses.

In the context of the disclosure, a machine-readable medium can be a tangible medium that can include or store a program to be used by or in combination with the instruction execution system, apparatus, or device. The machine-readable medium can be a machine-readable signal medium or a machine-readable storage medium. The machine-readable medium can include an electronic, magnetic, optical, electromagnetic, infrared, or semiconductor system, apparatus, or device, or any suitable combination of the above. Instances of the machine-readable storage medium include a portable computer disc, a hard disc, an RAM, an ROM, an EPROM or a flash memory, an optical fiber, a CD-ROM, an optical storage device, and a magnetic storage device that are each electrically connected through one or more wires, or any suitable combination of the above.

The foregoing outlines features of embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first semiconductor structure, comprising:
a function layer,
a wiring layer arranged on the function layer and comprising metal layers,
a bonding layer arranged on the wiring layer and comprising a first metal pad, and
a first via extending through at least one metal layer of the metal layers, and extending between a second metal pad of a first one of the metal layers and the first metal pad, and
a second semiconductor structure bonded with the first semiconductor structure by the bonding layer.

2. The semiconductor device of claim 1, wherein the first via extends through a plurality of metal layers of the metal layers.

3. The semiconductor device of claim 1, wherein the first via extends through one metal layer of the metal layers.

4. The semiconductor device of claim 1, wherein the first semiconductor structure further comprises:
a second via extending between a third metal pad of a second one of the metal layers and a fourth metal pad of the bonding layer without extending through the metal layers.

5. The semiconductor device of claim 1, wherein the first semiconductor structure further comprises:
a third via extending between two metal pads of two adjacent ones of the metal layers,
wherein the first via has a depth-to-width ratio greater than a depth-to-width ratio of the third via.

6. The semiconductor device of claim 5, wherein metal material of the third via is different from metal material of the first via; and
a cross-section of the wiring layer comprises a part of the third via and a part of the first via.

7. The semiconductor device of claim 6, wherein the third via comprises copper, and the first via comprises at least one of tungsten, titanium or aluminum.

8. The semiconductor device of claim 1, wherein an area of a cross-section of the first via at an end for contacting with the first metal pad is larger than an area of a cross-section of the first via at an end for contacting with the second metal pad.

9. The semiconductor device of claim 1, wherein the second semiconductor structure is bonded with the first semiconductor structure by another bonding layer of the second semiconductor structure and the bonding layer, and
wherein the first semiconductor structure is one of a memory chip or a peripheral chip for the memory chip, and the second semiconductor structure is the other one of the memory chip or the peripheral chip.

10. The semiconductor device of claim 9, wherein the memory chip is a NAND chip or a DRAM chip.

11. A system, comprising:
a memory, comprising:
a first semiconductor structure, comprising:
a function layer,
a wiring layer arranged on the function layer and comprising metal layers,
a bonding layer arranged on the wiring layer and comprising a first metal pad, and
a first via extending through at least one metal layer of the metal layers, and extending between a second metal pad of a first one of the metal layers and the first metal pad, and
a second semiconductor structure bonded with the first semiconductor structure by the bonding layer; and
a controller configured to control the memory.

12. The system of claim 11, wherein the first semiconductor structure is one of a memory chip or a peripheral chip for the memory chip, and the second semiconductor structure is the other one of the memory chip or the peripheral chip.

13. A method for manufacturing a semiconductor device, comprising:
forming a first semiconductor structure, comprising:
forming a function layer,
forming a wiring layer on the function layer, and the wiring layer comprising metal layers;
forming a first via in the wiring layer, and
forming a bonding layer on the wiring layer, and the bonding layer comprising a first metal pad,
wherein the first via extends through at least one metal layer of the metal layers and extends between a second metal pad of a first one of the metal layers and the first metal pad; and
bonding the first semiconductor structure with a second semiconductor structure by the bonding layer.

14. The method of claim 13, wherein forming the first via in the wiring layer comprises:
etching the wiring layer to form a first hole; and
depositing, by a physical vapor deposition (PVD) or chemical vapor deposition (CVD) process, metal material into the first hole, to form the first via.

15. The method of claim 14, wherein forming the bonding layer on the wiring layer comprises:
depositing insulation material on the wiring layer to form a insulation layer;
etching the insulation layer to form a second hole passing though the insulation layer and directly over the first via;
filling the second hole with metal material to form the first metal pad; and
polishing, by a chemical mechanical planarization (CMP) process, the insulation layer with the first metal pad, to form the bonding layer.

16. The method of claim 13, wherein forming the first semiconductor structure further comprises:
forming a second via in the wiring layer, and the second via extending between a third metal pad of a second one of the metal layers and a fourth metal pad of the bonding layer without extending through the metal layers.

17. The method of claim 13, wherein the wiring layer further comprises a third via extending between two metal pads of two adjacent ones of the metal layers, and
wherein the first via has a depth-to-width ratio greater than a depth-to-width ratio of the third via.

18. The method of claim 17, wherein metal material of the third via is different from metal material of the first via; and
a cross-section of the wiring layer comprises a part of the third via and a part of the first via.

19. The method of claim 18, wherein the third via comprises copper, and the first via comprises at least one of tungsten, titanium or aluminum.

20. The method of claim 13, wherein bonding the first semiconductor structure with the second semiconductor structure by the bonding layer comprises:
bonding the first semiconductor structure with a second semiconductor structure by another bonding layer of the second semiconductor structure and the bonding layer, and
wherein the first semiconductor structure is one of a memory chip or a peripheral chip for the memory chip, and the second semiconductor structure is the other one of the memory chip or the peripheral chip.
